(19) United States
(12) Patent Application Publication
(10) Pub. No.: US 2026/0206206 A1
(43) Pub. Date: Jul. 16, 2026

(54) SEMICONDUCTOR STRUCTURE AND METHOD FOR FORMING THE SAME

(71) Applicant: Fujian Jinhua Integrated Circuit Co., Ltd., Quanzhou City (CN)

(72) Inventors: Yi-Wang Jhan, Quanzhou City (CN); Fu-Che Lee, Quanzhou City (CN); Gang-Yi Lin, Quanzhou City (CN); An-Chi Liu, Quanzhou City (CN); Yifei Yan, Quanzhou City (CN); Yu-Cheng Tung, Quanzhou City (CN)

(73) Assignee: Fujian Jinhua Integrated Circuit Co., Ltd., Quanzhou City (CN)

(21) Appl. No.: 19/553,442

(22) Filed: Mar. 2, 2026

Related U.S. Application Data
(63) Continuation of application No. 17/378,789, filed on Jul. 19, 2021, now Pat. No. 12,593,437.

(30) Foreign Application Priority Data
Jun. 23, 2021 (CN) 202110697564.5
Jun. 23, 2021 (CN) 202121406525.7

(51) Int. Cl. H10B 12/00

(52) U.S. Cl. CPC H10B 12/30; H10B 12/02; H10B 12/50

(57) ABSTRACT

A semiconductor structure includes two first gate structures disposed on a first region of a substrate and a second gate structure disposed on a second region of a substrate, a first contact structure disposed between the two first gate structures, and a second contact structure disposed on a side of the second gate structure. A topmost surface of the first contact structure is not higher than topmost surfaces of the two first gate structures. A topmost surface of the second contact structure is higher than the topmost surface of the first contact structure. A bottommost surface of the first contact structure is flush with a bottommost surface of the second contact structure.

### CROSS REFERENCE TO RELATED APPLICATIONS

This application is a continuation application of U.S. Application No. 17/378,789, filed on July 19th, 2021. The content of the application is incorporated herein by reference.

### BACKGROUND OF THE INVENTION

### FIELD OF THE INVENTION

The present invention relates to a semiconductor structure and method for forming the same. More particularly, the present invention relates to a dynamic random access memory (DRAM) including a memory region and a peripheral region.

### DESCRIPTION OF THE PRIOR ART

Dynamic random access memory (DRAM) is one kind of volatile memory. A DRAM device usually includes a memory region comprising an array of memory cells and a peripheral region comprising control circuits for controlling and/or repairing the memory cells in the memory region. The control circuits in the peripheral region may address each of the memory cells in the memory region by plural columns of word lines and plural rows of bit lines traversing the memory region and electrically connected to each of the memory cells to perform reading, writing or erasing data. In advanced semiconductor manufacturing, the chip size of a DRAM device may be dramatically scaled down by adopting buried word-line or buried bit-lines architectures, by which the active areas of the memory cells may be arranged at a dense pitch for higher cell density.

A dynamic random access memory usually includes a memory region comprising memory cells and a peripheral region comprising peripheral circuits for controlling and/or repairing the memory cells in the memory region. The memory cells and the semiconductor devices of the peripheral circuits are formed integrally through a same manufacturing process. Therefore, it is important to provide peripheral semiconductor devices which are compliable with the manufacturing process of the memory cells.

### SUMMARY OF THE INVENTION

It is one objective of the present invention to provide a semiconductor structure and a method for forming the same, wherein the semiconductor structure has a memory region and a peripheral region, and the peripheral region of the semiconductor structure includes a share contact structure formed by a same manufacturing process for forming the storage node contacts of the memory cells in the memory region. The share contact structure provided by the present invention may be used to electrically connect two gate structures and a shared source/drain region between the two gate structures. For example, the share contact structure may be used in a fuse circuit in the peripheral region for repairing defective memory cells in the memory region.

According to one embodiment of the present invention, a semiconductor structure is provided. The semiconductor structure includes a substrate comprising a first region and a second region. A first dielectric layer is disposed on the first region and the second region of the substrate. Two first gate structures are disposed in the first dielectric layer on the first region and a second gate structure disposed in the first dielectric layer on the second region, wherein each of the first gate structures comprises a first electrode portion and a first hard mask portion disposed on the first electrode portion, the second gate structure comprises a second electrode portion and a second hard mask portion disposed on the second electrode portion. A first contact structure is disposed on the substrate and between the two first gate structures, wherein the first contact structure has a lower portion and an upper portion disposed on the lower portion, wherein a width of the upper portion is larger than a width of the lower portion, wherein a topmost surface of the upper portion of the first contact structure is not higher than topmost surfaces of the first hard mask portions of the two first gate structures, a bottommost surface of the lower portion is in direct contact with the substrate, the upper portion is in direct contact with sidewalls of the first hard mask portions and topmost surfaces of the first electrode portion, the lower portion is in direct contact with sidewalls of the first electrode portion. A second dielectric layer is disposed on the first dielectric layer on the second region. A second contact structure is disposed on the substrate adjacent to a side of the second gate structure and through the first dielectric layer and the second dielectric layer, wherein a topmost surface of the second contact structure is higher than the topmost surface of the upper portion of the first contact structure, a bottommost surface of the two second contact structure is in direct contact with the substrate and flush with the bottommost surface of the lower portion of the first contact structure. A passivation layer is disposed on the first dielectric layer and in direct contact with a sidewall of the second dielectric layer and a sidewall of the second contact structure. An interlayer dielectric layer is disposed on the first region and the second region of the substrate and covering the two first gate structures, the first contact structure, the second gate structure, the second contact structure and the passivation layer.

According to another embodiment of the present invention, a semiconductor structure is disclosed, which includes a substrate, a first dielectric layer on the substrate, a second dielectric layer on the first dielectric layer, a contact structure on the substrate and through the first dielectric layer and the second dielectric layer, and a passivation layer on the first dielectric layer and in direct contact with a sidewall of the second dielectric layer and a sidewall of the contact structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. Relative dimensions and proportions of parts of the drawings have been shown exaggerated or reduced in size, for the sake of clarity and convenience in the drawings. The same reference signs are generally used to refer to corresponding or similar features in modified and different embodiments.

FIG. 1 is a schematic top plan view of a semiconductor structure according to one embodiment of the present invention.

FIG. 2 to FIG. 9 are schematic diagrams illustrating successive steps of a method for forming the semiconductor structure according to one embodiment of the present invention.

FIG. 10 is a schematic diagram illustrating a cross-sectional view of a semiconductor structure according to another embodiment of the present invention.

### DETAILED DESCRIPTION

To provide a better understanding of the present invention to those of ordinary skill in the art, several exemplary embodiments will be detailed as follows, with reference to the accompanying drawings using numbered elements to elaborate the contents and effects to be achieved.

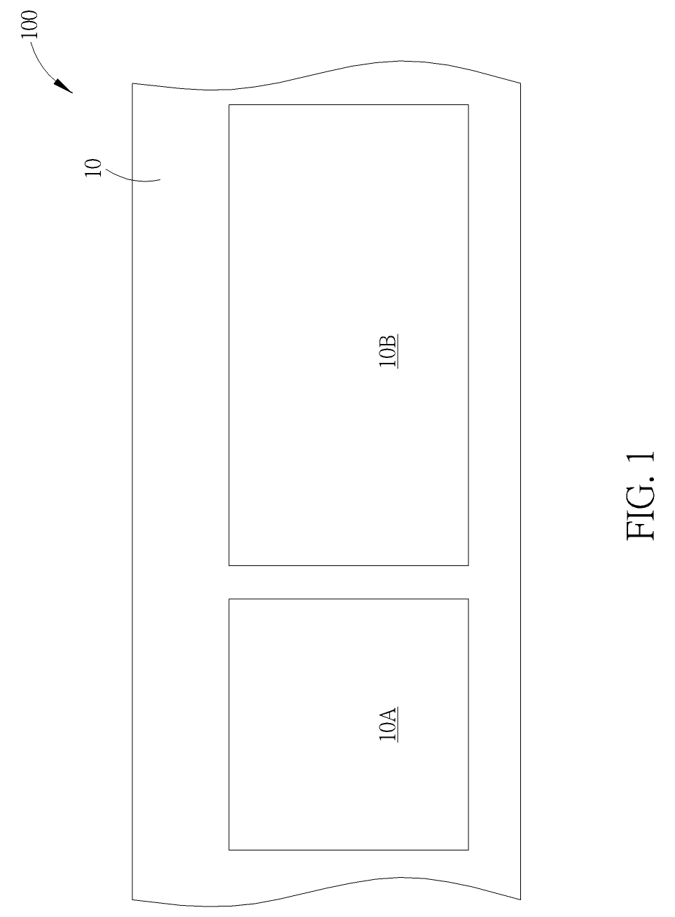

FIG. 1 is a schematic top plan view of a semiconductor structure 100 according to one embodiment of the present invention. As shown in FIG. 1, the semiconductor structure 100 includes a substrate 10 having a peripheral region 10A and a memory region 10B defined thereon. The shapes and arrangements of the peripheral region 10A and the memory region 10B shown in FIG. 1 are only examples for the purpose of illustration, and should not be limitations to the present invention.

The peripheral region 10A may include peripheral circuits that control operations and input/output of the memory cells in the memory region 10B, such as drivers, buffers, amplifiers, and decoders, but are not limited thereto. The peripheral region 10A may also include circuits for repairing defective memory cells, such as fuse circuits. The memory region 10B may include an array of memory cells, for example, DRAM cells. The semiconductor devices of the peripheral circuits in the peripheral region 10A and the DRAM cells in the memory region 10B are integrally formed on the substrate 10 by a same manufacturing process.

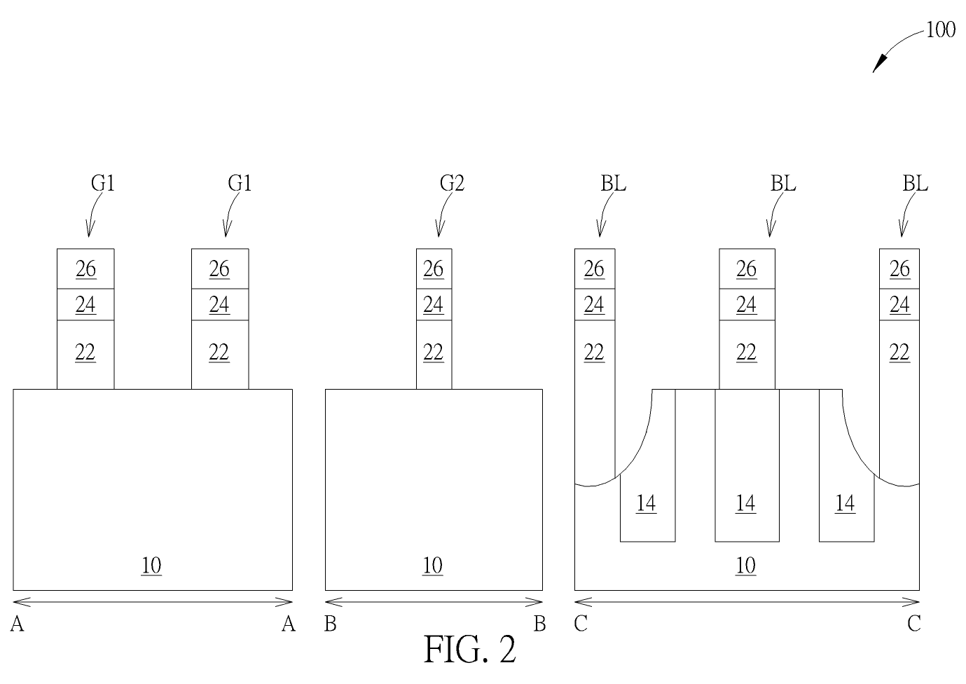

FIG. 2 to FIG. 9 are schematic diagrams illustrating successive steps of a method for forming the semiconductor structure according to one embodiment of the present invention. The semiconductor structure shown in FIG. 2 to FIG. 9 may have a substrate and peripheral region and a memory region as shown in FIG. 1. The left portions of FIG. 2 to FIG. 9 are cross-sectional views of a first device region AA of a peripheral region of the semiconductor structure. The middle portions of FIG. 2 to FIG. 9 are cross-sectional views of a second device region BB of the peripheral region of the semiconductor structure. The right portions of FIG. 2 to FIG. 9 are cross-sectional views of a memory region CC of the semiconductor structure.

Please refer to FIG. 2, a substrate 10 is provided. A plurality of isolation structures 14 such as shallow trench isolations (STI) may be formed in the substrate 10 to define a plurality of active regions of the semiconductor devices (not shown) in the peripheral region 10A of the substrate 10 and a plurality of active regions (not shown) of the memory cells (not shown) in the memory region 10B of the substrate 10. Furthermore, a plurality of buried word lines (not shown) may be formed in the substrate 10 and cut through the active regions (not shown) of the memory cells.

As shown in FIG. 2, two first gate structures G1, a second gate structure G2, and a plurality of bit lines BL are formed on the substrate 10 at the same time by the same manufacturing process. For example, a semiconductor material layer (not shown), a metal material layer (not shown), and a hard mask material layer (not shown) may be successively formed on the peripheral region and the memory region of the substrate 10. After that, a patterning process such as a photolithography-etching process may be performed to pattern the hard mask material layer, and a subsequent etching process using the patterned hard mask material layer as an etching mask may be performed to etch and remove the unnecessary portions of the semiconductor material layer and the metal material layer, such that the first gate structures G1, the second gate structure G2, and the bit lines BL may be obtained.

As shown in FIG. 2, the first gate structures G1, the second gate structure G2, and the bit lines BL respectively include a lower gate portion 22, an upper gate portion 24 on the lower gate portion 22, and a hard mask portion 26 on the upper gate portion 24. According to an embodiment, the lower gate portion 22 may include a semiconductor material, such as polysilicon. The upper gate portion 24 may include a conductive material, such as aluminum (Al), tungsten (W), copper (Cu), titanium (Ti), titanium aluminum alloy (TiAl), or other low-resistivity metal materials. The hard mask portion 26 may include silicon nitride (SiN), silicon oxynitride (SiON), silicon carbon nitride (SiCN), or other dielectric materials. A gate dielectric layer (not shown) may be disposed between the substrate 10 and the lower gate portions 22 of the first gate structures G1 and the second gate structures G2.

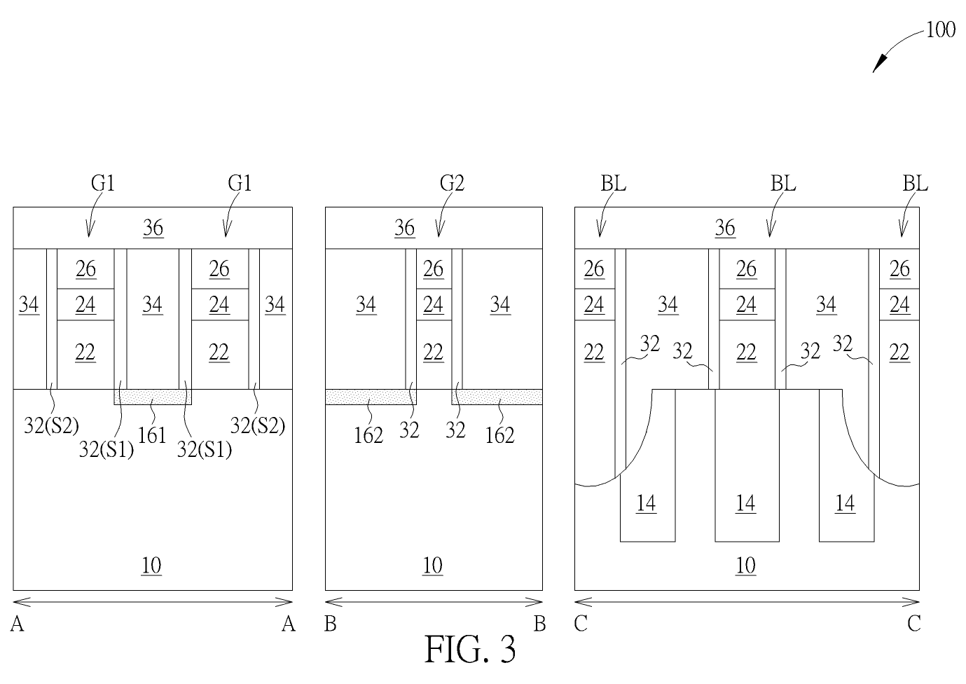

Please refer to FIG. 3. Subsequently, the spacers 32 may be formed on sidewalls of the first gate structures G1, the second gate structures G2, and the bit lines BL, and the doped region 161 in the substrate 10 between the first gate structures G1 and the doped regions 162 in the substrate 10 at two sides of the second gate structures G2 may be formed in the active regions (not shown) of the peripheral region 10A of the substrate 10. The positions of the doped region 161 and the doped regions 162 shown in FIG. 3 are only examples and should not be taken as limitations to the present invention. After that, a first dielectric layer 34 may be formed on the substrate 10, and a planarization process may be carried out to remove a portion of the first dielectric layer 34 until the top surfaces of the first gate structures G1, the second gate structure G2, and the bit lines BL are exposed. After that, a second dielectric layer 36 is formed on the first dielectric layer 34 and covering the exposed top surfaces of the first gate structures G1, the second gate structure G2, and the bit lines BL. According to an embodiment, the materials of the first dielectric layer 34 and the second dielectric layer 36 may include silicon oxide (SiO₂), silicon nitride (SiN), silicon oxynitride (SiON), silicon carbon nitride (SiCN), or other dielectric materials. According to an embodiment, the first dielectric layer 34 may include silicon oxide (SiO₂), and the second dielectric layer 36 may include silicon nitride (SiN) but is not limited thereto.

According to an embodiment, the spacers 32 may be formed by depositing at least a spacer material layer (not shown) on the substrate 10 and conformally covering the top surfaces and sidewalls of the first gate structures G1, the second gate structure G2, and the bit lines BL. An etching process such as a dry etching process may be performed to anisotropically etch and remove the unnecessary portions of the spacer material layer. The remaining portions of the spacer material layer on the sidewalls of the first gate structures G1, the second gate structure G2, and the bit lines BL become the spacers 32. The material of the spacers 32 may include silicon nitride (SiN), silicon oxynitride (SiON), silicon carbon nitride (SiCN), or other dielectric materials. According to an embodiment, the spacers 32 may respectively have a single-layered structure or a multi-layered structure. In the following description, the portions of the spacers 32 disposed on the inner sides of the first gate structures G1 (formed on the two adjacent sidewalls of the first gate structures G1 and between the two first gate structures G1) are also referred to as the inner spacers S1. The portions of the spacers 32 disposed on the outer sides of the first gate structures G1 (formed on the sidewalls of the first gate structures G1 opposite to the inner spacers S1) are referred to as the outer spacers S2.

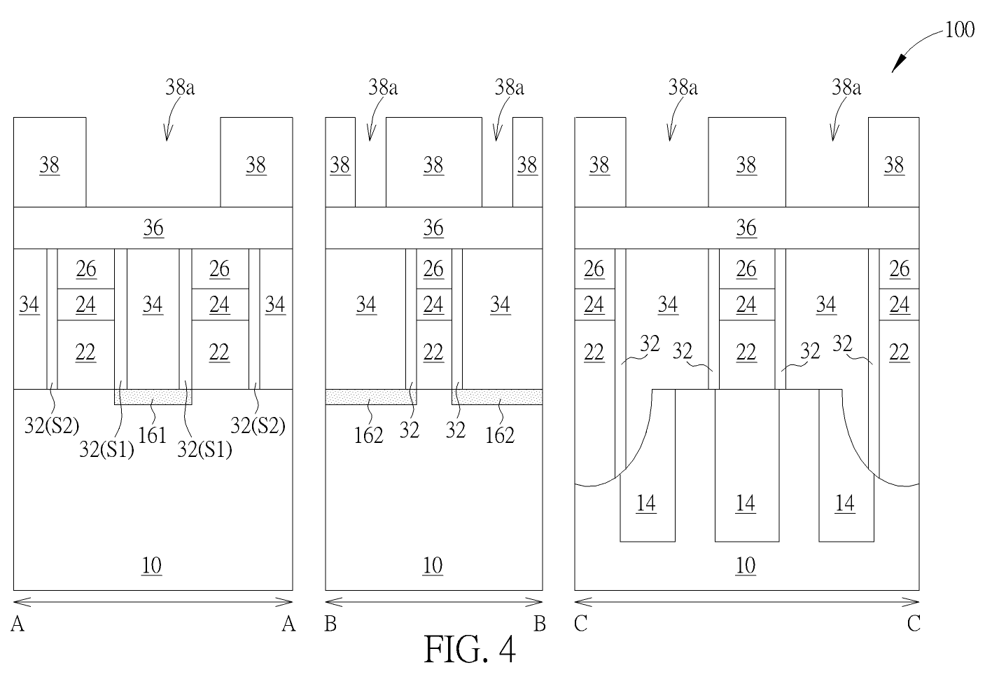

Please refer to FIG. 4. Subsequently, a patterned mask layer 38 may be formed on the second dielectric layer 36. The patterned mask layer 38 includes a plurality of mask openings 38a that expose predetermined portions of the second dielectric layer 36.

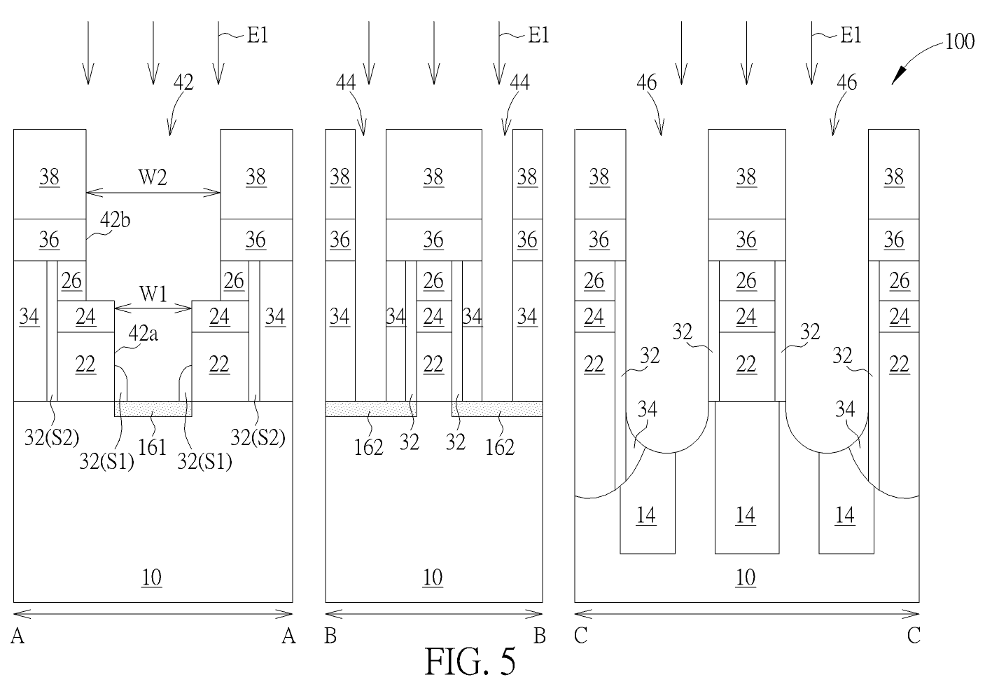

Please refer to FIG. 5. Subsequently, a contact etching process E1 such as a dry etching process is performed, using the patterned mask layer 38 as an etching mask to etch and remove the exposed portions of the second dielectric layer 36 and the first dielectric layer 34, thereby forming the first contact opening 42, the second contact openings 44, and the storage node contact openings 46. The first contact opening 42 is between the two first gate structures G1 and through the second dielectric layer 36 and the first dielectric layer 34 to expose portions of the doped region 161 in the substrate 10. The second contact openings 44 are at two sides of the second gate structure G2 and through the second dielectric layer 36 and the first dielectric layer 34 to expose portions of the doped region 162 at two sides of the second gate structure G2. The storage node contact openings 46 are between the bit lines BL and through the second dielectric layer 36 and the first dielectric layer 34 to expose portions of the active regions (not shown) of the memory cells.

According to an embodiment, the hard mask portions 26 of the first gate structures G1 may be partially removed during the contact etching process E1. Accordingly, the first contact opening 42 may have a T-shaped cross-sectional profile. As shown in FIG. 5, the first contact opening 42 has a first portion 42a having a first width W1 and a second portion 42b over the first portion 42a and having a second width W2. The first width W1 is smaller than the second width W2. The first portion 42a may expose the substrate 10 between the first gate structures G1. The second portion 42b may expose top surfaces of the upper gate portions 24 and sidewalls of the hard mask portions 26 of the first gate structures G1.

According to an embodiment, during the contact etching process E1, the inner spacers S1 between the first gate structures G1 may be partially removed. Therefore, the sidewalls of the lower gate portions 22 and the sidewalls of the upper gate portions 24 of the first gate structures G1 are exposed from the first portion 42a of the first contact opening 42.

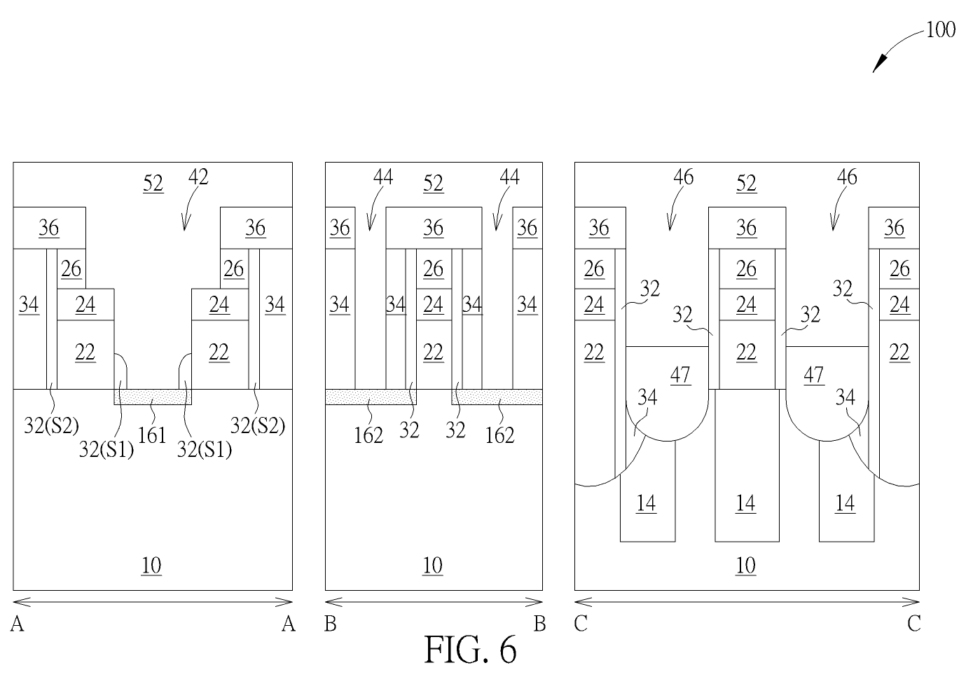

Please refer to FIG. 6. After removing the patterned mask layer 38, lower gate portions 45 may be selectively formed on the exposed active regions (not shown) of the memory cells and fill the lower portions of the storage node contact openings 46. Subsequently, a conductive layer 52 may be formed on the second dielectric layer 36 and completely fills the first contact opening 42, the second contact openings 44, and the storage node contact openings 46. The conductive layer 52 may include a metal, for example, tungsten (W).

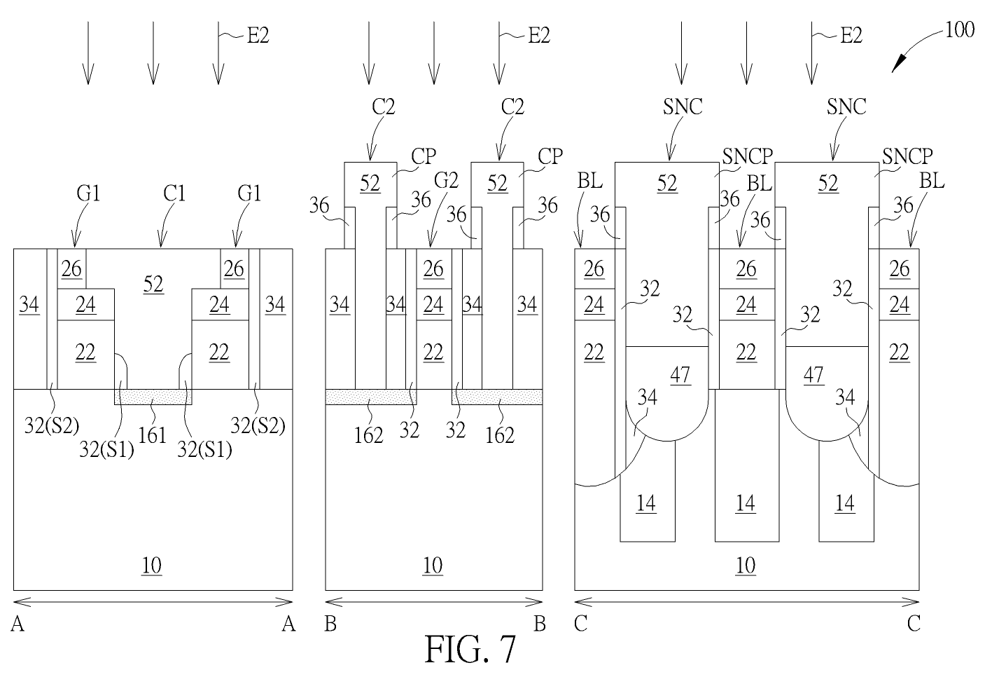

Subsequently, as shown in FIG. 7, after forming another patterned mask layer (not shown) on the conductive layer 52 to cover portions of the conductive layer 52, a recessing process E2 may be performed, using the patterned mask layer (not shown) as an etching mask to etch and pattern the conductive layer 52 and also remove the exposed portions of the second dielectric layer 36, thereby forming the first contact structure C1 in the first contact opening 42, the second contact structures C2 respectively in the second contact openings 44 and having a pad portions CP outside the second contact openings 44, the storage node contacts SNC respectively in the storage node contact openings 46 and having a pad portions SNCP outside the storage node contact openings 46. It is noteworthy that the first contact structure C1, the second contact structures C2, and the storage node contacts SNC respectively have a one-piece configuration.

According to an embodiment, after the recessing process E2, the conductive layer 52 in the first contact opening 42 is recessed to have a top surface substantially flush with the top surfaces of the hard mask portion 26, the top surfaces of the outer spacers S2, and the top surfaces of the first dielectric layer 34 after the recessing process E2.

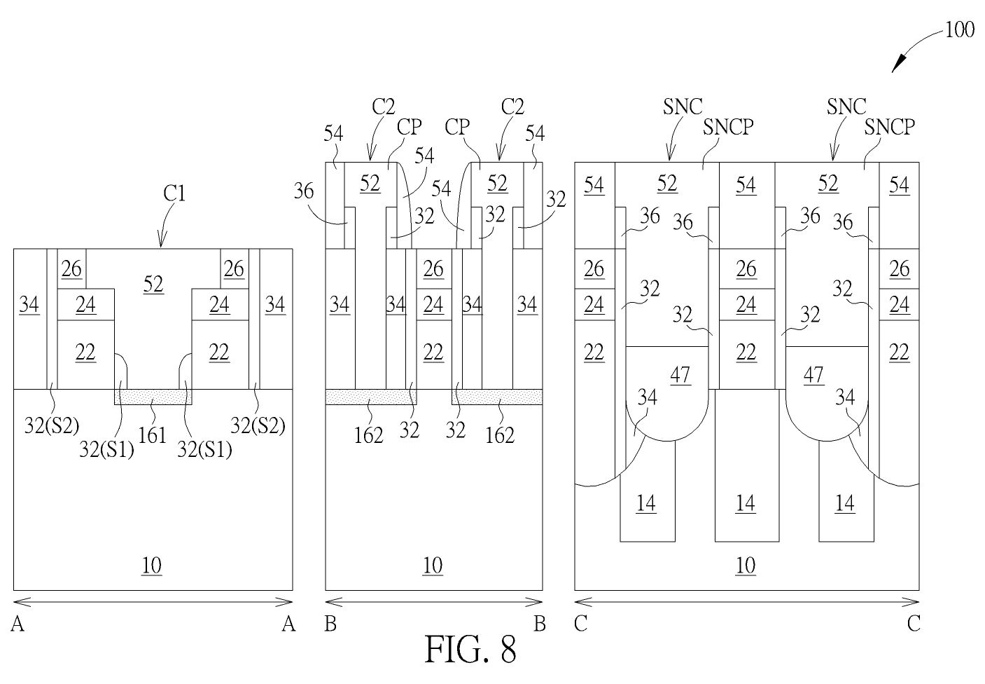

Please refer to FIG. 8. Subsequently, a passivation layer 54 may be formed on the first dielectric layer 34, and an etching process (not shown) such as a dry etching process may be performed to remove a portion of the passivation layer 54 until the top surface of the first contact structure C1, the top surfaces of the pad portions CP of the second contact structure C2, and the top surfaces of the pad portions SNCP of the storage node contacts SNC are exposed. According to an embodiment, a remaining portion of the passivation layer 54 may form spacers on sidewalls of the pad portions CP and the portions of the second dielectric layer 36 under the pad portions CP. Another remaining portion of the passivation layer 54 may completely fill the spaces between the pad portions SNCP. According to an embodiment, the passivation layer 54 may include silicon nitride (SiN).

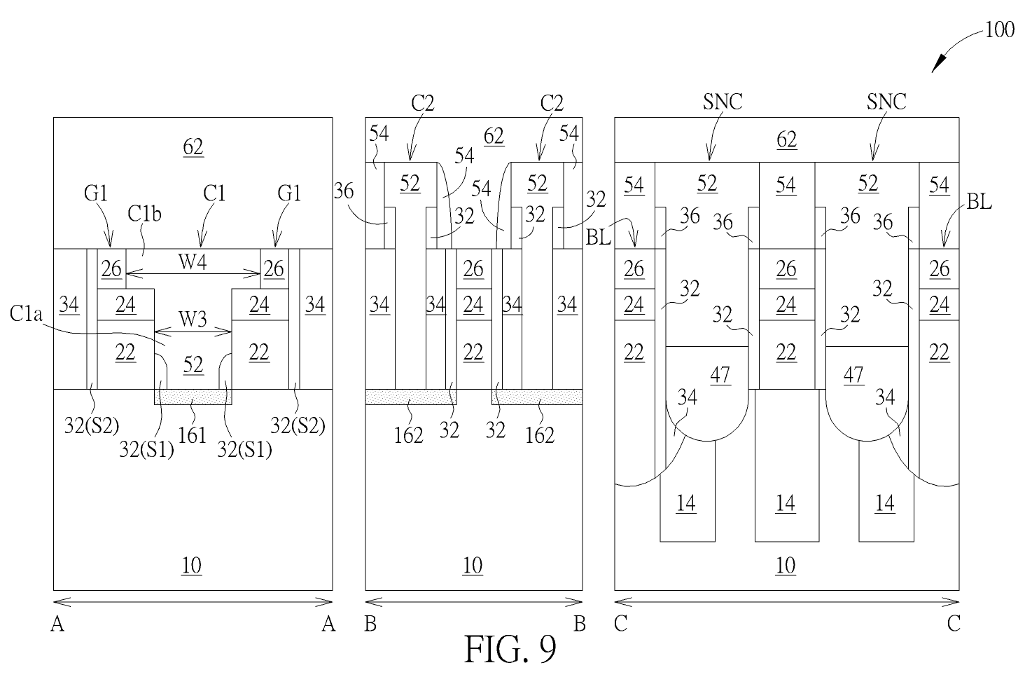

Please refer to FIG. 9. Subsequently, an interlayer dielectric layer 62 is formed on the first contact structure C1, the pad portions CP, and the pad portions SNCP. The interlayer dielectric layer 62 also fills the space between the pad portions CP. The materials of the interlayer dielectric layer 62 may include silicon oxide (SiO₂), silicon nitride (SiN), silicon oxynitride (SiON), silicon carbon nitride (SiCN), or other dielectric materials. In later process steps (not shown), after planarizing the interlayer dielectric layer 62, a plurality of interconnect structure (not shown) may be formed in the interlayer dielectric layer 62 to electrically connect to the first contact structure C1, the pad portions CP of the second contact structures C2, and the pad portions SNCP of the storage node contacts SNC.

In light of the above and as shown in FIG. 9, the semiconductor structure 100 provided by the present invention includes a substrate 10 having a peripheral region 10A and a memory region 10B defined thereon. A first contact structure C1 is disposed on the peripheral region 10A of the substrate 10. The first contact structure C1 has a one-piece configuration and has a T-shaped cross-sectional profile having a first portion C1a directly contacting the substrate 10 and a second portion C1b disposed on the first portion C1a. A width W4 of the second portion C1b is larger than a width W3 of the first portion C1a.

Two first gate structures G1 are disposed on the substrate 10 and at two sides of the first contact structure C1. Each of the first gate structures G1 includes a lower gate portion 22 on the substrate 10, an upper gate portion 24 on the lower gate portion 22, and a hard mask portion 26 on the upper gate portion 24. The lower gate portion 22 and the upper gate portion 24 altogether are also referred to as the electrode portion of the first gate structure G1. As shown in FIG. 9, a top surface of the first contact structure C1 (that is, the top surface of the second portion C1b of the first contact structure C1) is flush with the top surfaces of the first gate structures G1 (that is, the top surfaces of the hard mask portions 26 of the first gate structures G1).

The first portion C1a of the first contact structure C1 directly contacts the sidewalls of the lower gate portions 22 and the sidewalls of the upper gate portions 24 of the first gate structures G1. The second portion C1b of the first contact structure C1 directly contacts top surfaces of the upper gate portions 24 and sidewall of the hard mask portions 26 of the first gate structures G1. The first contact structure C1 is a share contact that is electrically connected to the two first gate structures G1 and the substrate 10 between the two first gate structures G1. According to an embodiment, the first contact structure C1 may be used to connect the two first gate structures G1 and the shared source/drain region (the doped region 161) between the two first gate structures G1 in order to reduce the area of the peripheral circuits. For example, the first contact structure C1 provided by the present invention may be used in a fuse circuit in the peripheral region 10A which is for repairing defective memory cells in the memory region 10B.

Two inner spacers S1 may be disposed on the substrate 10 and sandwiched between the first portion C1a of the first contact structure C1 and the first gate structures G1. The top surfaces of the inner spacers S1 are lower than top surfaces of the upper gate portions 24 of the first gate structures G1. In other words, the top surfaces of the inner spacers S1 are lower than top surfaces of electrode portion of the first gate structures G1

Two outer spacers S2 may be disposed on the substrate 10 and on the sidewalls of the first gate structures G1 opposite to the inner spacers S1. The sidewalls of the lower gate portions 22 and the sidewalls of the upper gate portions 24 of the first gate structures G1 opposite to the inner spacers S1 may be fully covered by the two outer spacers S2. The sidewalls of the hard mask portions 26 of the first gate structures G1 opposite to the first contact structure C1 is at least partially covered by the two outer spacers S2.

A second gate structure G2 may be disposed on the peripheral region 10A of the substrate 10, and two second contact structures C2 may be disposed on the substrate 10 and at two sides of the second gate structure G2. The second contact structures C2 respectively have a lower portion directly contacting the substrate 10 and surrounded by the first dielectric layer 34 and an upper portion disposed on the lower portion and surrounded by a portion of the second dielectric layer 36. A pad portion CP of the second contact structure C2 extends laterally to cover the top surface of the portion of the second dielectric layer 36 surrounding the upper portion of the second contact structure C2.

A plurality of bit lines BL may be disposed on the memory region 10B of the substrate 10, and a plurality of storage node contacts SNC may be disposed on the substrate 10 and between the bit lines BL. The storage node contacts SNC respectively have a lower portion directly contacting the substrate 10 and surrounded by the first dielectric layer 34 and an upper portion disposed on the lower portion and surrounded by a portion of the second dielectric layer 36. A pad portion SNCP of the storage node contact SNC extends laterally to cover the top surface of the portion of the second dielectric layer 36 surrounding the upper portion of the storage node contacts SNC.

The top surfaces of the pad portions CP and the top surfaces of the pad portions SNCP are substantially flush with each other, and are at a position higher than the top surface of the first contact structure C1 (the top surface of the second portion 42b).

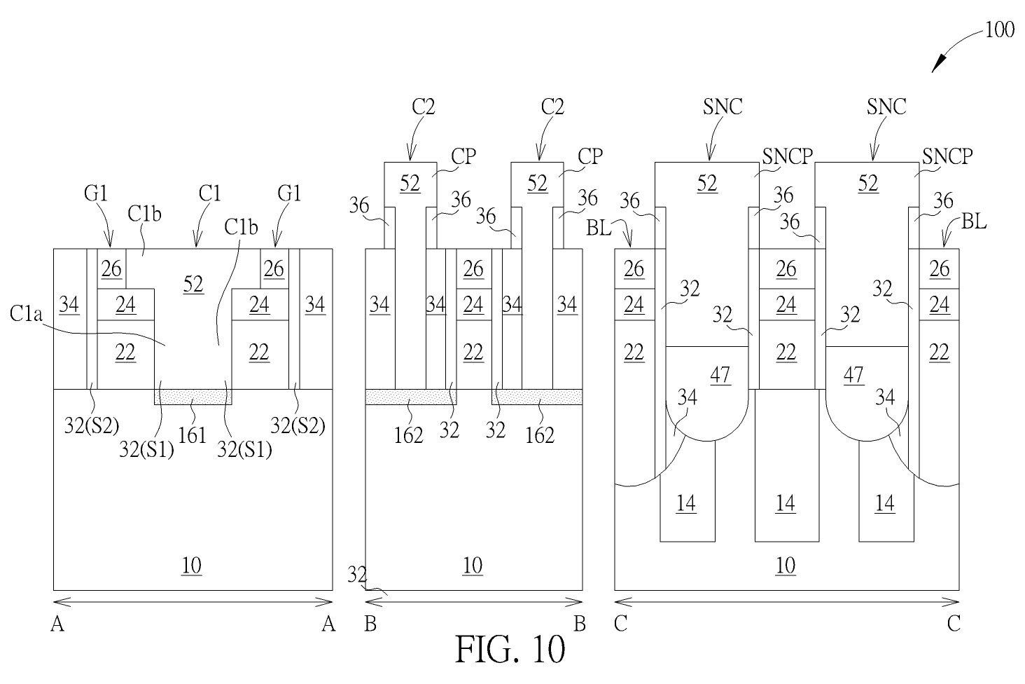

Please refer to FIG. 10, which is a schematic diagram illustrating a cross-sectional view of a semiconductor structure according to another embodiment of the present invention. To simplify the description, identical components in the embodiment shown in FIG. 10 and the embodiment shown in FIG. 7 are marked with identical symbols. A difference between the embodiment shown in FIG. 10 and the embodiment shown in FIG. 7 is that, the inner spacers S1 may be completely removed during the contact etching process E1. Therefore, sidewalls of the lowest portions of the first gate structures G1, that is, the lowest portions of the lower gate portions 22 may be fully contacted by the first portion C1a of the first contact structure C1.

In conclusion, the present invention provides a semiconductor structure having different types of contact structures (the first contact structure C1 and the second contact structure C2) which may be conveniently formed by the manufacturing process for forming the storage node contacts, and may be used to form different peripheral circuits in the peripheral region of the semiconductor structure. For example, the first contact structure may be a share contact to electrically connect two gate structures and a shared source/drain region between the two gate structures, while the second contact structure may be used to electrically connect a source/drain region of a transistor. The manufacturing process of the semiconductor structure provided by the present invention may be simplified.

The foregoing outlines the features of several embodiments, enabling those skilled in the art to fully appreciate the aspects of the present disclosure. Those skilled in the art should recognize that the present disclosure provides a foundation for designing or modifying other processes and structures to achieve substantially the same functions and/or substantially the same results as those of the embodiments introduced herein. Furthermore, such equivalent arrangements do not deviate from the spirit and scope of the present disclosure, and various changes, substitutions, and alterations may be made without so departing.

What is claimed is:

1. A semiconductor structure, comprising:
a substrate comprising a first region and a second region;
a first dielectric layer on the first region and the second region of the substrate;
two first gate structures disposed in the first dielectric layer on the first region and a second gate structure disposed in the first dielectric layer on the second region, wherein each of the first gate structures comprises a first electrode portion and a first hard mask portion disposed on the first electrode portion, the second gate structure comprises a second electrode portion and a second hard mask portion disposed on the second electrode portion;
a first contact structure disposed on the substrate and between the two first gate structures, wherein the first contact structure has a lower portion and an upper portion disposed on the lower portion, wherein a width of the upper portion of the first contact structure is larger than a width of the lower portion of the first contact structure, wherein a topmost surface of the upper portion of the first contact structure is not higher than topmost surfaces of the first hard mask portions of the two first gate structures, a bottommost surface of the lower portion of the first contact structure is in direct contact with the substrate, the upper portion of the first contact structure is in direct contact with sidewalls of the first hard mask portions and topmost surfaces of the first electrode portion, the lower portion of the first contact structure is in direct contact with sidewalls of the first electrode portion;
a second dielectric layer on the first dielectric layer on the second region;
a second contact structure disposed on the substrate adjacent to a side of the second gate structure and through the first dielectric layer and the second dielectric layer, wherein a topmost surface of the second contact structure is higher than the topmost surface of the upper portion of the first contact structure, a bottommost surface of the second contact structure is in direct contact with the substrate and flush with the bottommost surface of the lower portion of the first contact structure;
a passivation layer on the first dielectric layer and in direct contact with a sidewall of the second dielectric layer and a sidewall of the second contact structure; and
an interlayer dielectric layer disposed on the first region and the second region of the substrate and covering the two first gate structures, the first contact structure, the second gate structure, the second contact structure and the passivation layer.

2. The semiconductor structure according to claim 1, wherein the second contact structure comprises a lower portion and an upper portion disposed on the lower portion, wherein a sidewall of the lower portion of the second contact structure is in direct contact with the first dielectric layer and the second dielectric layer, a sidewall of the upper portion of the second contact structure is in direct contact with the passivation layer.

3. The semiconductor structure according to claim 2, wherein the upper portion of the second contact structure is in direct contact with a top surface of the second dielectric layer.

4. The semiconductor structure according to claim 2, wherein in a direction parallel to a surface of the substrate, a width of the upper portion of the second contact structure is larger than a width of the lower portion of the second contact structure.

5. The semiconductor structure according to claim 1, wherein a bottom surface of the second dielectric layer and a bottom surface of the passivation layer are flush to each other and in direct contact with a surface of the first dielectric layer.

6. The semiconductor structure according to claim 1, further comprising a first spacer disposed between each of the two first gate structures and the first dielectric layer, wherein a top surface of the first spacer is in direct contact with a bottom surface of the interlayer dielectric layer.

7. The semiconductor structure according to claim 1, further comprising a second spacer disposed between the first dielectric layer and the second gate structure, wherein a top surface of the second spacer is in direct contact with a bottom surface of the passivation layer.

8. The semiconductor structure according to claim 1, further comprising another second contact structure disposed on the substrate adjacent to another side of the second gate structure, wherein the passivation layer on the sidewall of the second contact structure and the passivation layer on the sidewall of the another second contact structure are separated by the interlayer dielectric layer.

9. The semiconductor structure according to claim 1, wherein a top surface of the interlayer dielectric layer on the first region and a top surface of the interlayer dielectric layer on the second region are flush to each other.

10. The semiconductor structure according to claim 1, wherein the first electrode portions of the two first gate structures respectively comprise:
a lower gate portion; and
an upper gate portion on the lower gate portion, wherein the lower portion of the first contact structure directly contacts an inner sidewall of the lower gate portion and an inner sidewall of the upper gate portion.

11. The semiconductor structure according to claim 10, wherein the lower portion of the first contact structure directly contacts lowest portions of the lower gate portions of the two first gate structures, respectively.

12. The semiconductor structure according to claim 10, wherein the upper portion of the first contact structure directly contacts topmost surfaces of the upper gate portions of the two first gate structures, respectively.

13. The semiconductor structure according to claim 10, further comprises:
two inner spacers disposed on the substrate and sandwiched between the lower portion of the first contact structure and the two first gate structures, wherein topmost surfaces of the two inner spacers are lower than topmost surfaces of the upper gate portions of the two first gate structures.

14. The semiconductor structure according to claim 1, wherein the first contact structure and the second contact structure respectively have a one-piece configuration.

15. A semiconductor structure, comprising:
a substrate;
a first dielectric layer on the substrate;
a second dielectric layer on the first dielectric layer;
a contact structure on the substrate and through the first dielectric layer and the second dielectric layer; and
a passivation layer on the first dielectric layer and in direct contact with a sidewall of the second dielectric layer and a sidewall of the contact structure.

16. The semiconductor structure according to claim 15, wherein the contact structure comprising:
a lower portion in direct contact with a sidewall of the passivation layer; and
an upper portion in direct contact with a sidewall of the first dielectric layer and another sidewall of the second dielectric layer.

17. The semiconductor structure according to claim 16, wherein in a direction parallel to a surface of the substrate, a width of the lower portion is larger than a width of the upper portion.

18. The semiconductor structure according to claim 15, wherein a bottom surface of the second dielectric layer and a bottom surface of the passivation layer are flush to each other and in direct contact with a surface of the first dielectric layer.

19. The semiconductor structure according to claim 15, further comprising an interlayer dielectric layer on the contact structure and the passivation layer.

20. The semiconductor structure according to claim 15, further comprising a gate structure on the substrate and spaced from the contact structure by the first dielectric layer, wherein gate structure comprises a semiconductor portion, a metal portion on the semiconductor portion, and a hard mask portion on the metal portion, wherein a top surface of the first dielectric layer is flush with a top surface of the hard mask portion.

21. The semiconductor structure according to claim 15, further comprising a spacer disposed on the substrate and between the first dielectric layer and the gate structure, wherein a top surface of the spacer is in direct contact with a bottom surface of the passivation.

22. The semiconductor structure according to claim 15, further comprising an interlayer dielectric layer on the contact structure, the passivation layer and the gate structure.

23. The semiconductor structure according to claim 15, wherein the contact structure is in direct contact with a top surface of the second dielectric layer.
